(19) United States
(12) Patent Application Publication
(10) Pub. No.: US 2026/0009137 A1
(43) Pub. Date: Jan. 8, 2026

(54) Substrate Processing Apparatus and State Determination Method

(71) Applicant: Tokyo Electron Limited, Tokyo (JP)

(72) Inventor: Takahiro KAWAWA, Yamanashi (JP)

(21) Appl. No.: 19/244,952

(22) Filed: Jun. 20, 2025

(30) Foreign Application Priority Data
Jul. 3, 2024 (JP) 2024-107615

(51) Int. Cl. C23C 16/458; C23C 16/52

(52) U.S. Cl. CPC C23C 16/4586; C23C 16/52

(57) ABSTRACT

There is a substrate processing apparatus comprising: a substrate placing table having an electrostatic chuck configured to electrostatically attract a substrate by applying a voltage to an electrode of the electrostatic chuck; a lift pin configured to protrude from and retract below a substrate placing surface of the substrate placing table; a driving mechanism configured to raise and lower the lift pin; an electrostatic capacitance detection part configured to detect an electrostatic capacitance of the electrostatic chuck; and a controller configured to determine a state of the electrostatic chuck based on the electrostatic capacitance detected by the electrostatic capacitance detection part.

### CROSS-REFERENCE TO RELATED APPLICATIONS

This application claims priority to Japanese Patent Application No. 2024-107615 filed on Jul. 3, 2024, the entire contents of which are incorporated herein by reference.

### TECHNICAL FIELD

The present disclosure relates to a substrate processing apparatus and a state determination method.

### BACKGROUND

Japanese Laid-open Patent Publication No. 2008-47564 discloses a vacuum processing apparatus in which a substrate is placed on an electrostatic chuck provided on a placing table in a vacuum chamber, and a chuck voltage is applied to a chuck electrode to electrostatically attract the substrate to the electrostatic chuck and process the substrate. The vacuum processing apparatus includes: a power supply for applying a diagnostic voltage lower than the chuck voltage to the chuck electrode used during vacuum processing; a measurement part for measuring electrical characteristics of the electrostatic chuck when the diagnostic voltage is applied to the chuck electrode and acquiring the measurement data; and a diagnostic part for diagnosing whether the electrostatic chuck is usable based on the measurement data acquired by the measurement part and the preset setting data.

### SUMMARY

One aspect of the present disclosure provides a substrate processing apparatus and a state determination method for determining a state of a substrate placing table.

In accordance with an exemplary embodiment of the present disclosure, there is a substrate processing apparatus comprising: a substrate placing table having an electrostatic chuck configured to electrostatically attract a substrate by applying a voltage to an electrode of the electrostatic chuck; a lift pin configured to protrude from and retract below a substrate placing surface of the substrate placing table; a driving mechanism configured to raise and lower the lift pin; an electrostatic capacitance detection part configured to detect an electrostatic capacitance of the electrostatic chuck; and a controller configured to determine a state of the electrostatic chuck based on the electrostatic capacitance detected by the electrostatic capacitance detection part.

### BRIEF DESCRIPTION OF THE DRAWINGS

FIG. 1 is an example of a cross-sectional view showing a substrate processing apparatus according to the present embodiment.

FIG. 2 is an example of a flowchart showing the operation of the substrate processing apparatus according to the present embodiment.

FIG. 3 is an example of a diagram explaining states in which capacitance is measured.

FIGS. 4A to 4F are examples of partially enlarged cross-sectional views explaining a state of a substrate placing table in respective states of the electrostatic capacitance measurement.

FIG. 5 is an example of a graph of an electrostatic capacitance.

### DETAILED DESCRIPTION

Hereinafter, embodiments of the present disclosure will be described with reference to the accompanying drawings. Like reference numerals will be given to like parts throughout the drawings, and redundant description thereof may be omitted.

### Substrate Processing Apparatus 1

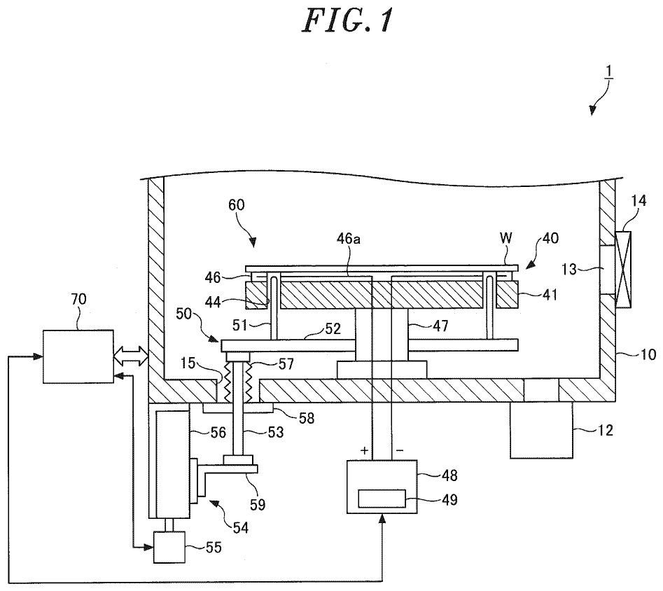

A substrate processing apparatus 1 according to the present embodiment will be described with reference to FIG. 1. FIG. 1 is an example of a cross-sectional view showing the substrate processing apparatus 1 according to the present embodiment. The substrate processing apparatus 1 is an apparatus that performs desired substrate processing (e.g., film formation, etching, heat treatment, or the like) on a substrate W placed on a substrate placing table 40. Further, when the substrate processing apparatus 1 is a film forming apparatus, it may be any apparatus, such as a CVD apparatus, an ALD apparatus, and a PVD apparatus.

As shown in FIG. 1, the substrate processing apparatus 1 includes a processing chamber 10, a substrate placing table 40, a substrate lifting mechanism 50, and a controller 70. Further, the substrate placing table 40 and the substrate lifting mechanism 50 constitute a substrate placing mechanism 60.

The processing chamber 10 accommodates the substrate W, and an inner atmosphere of the processing chamber 10 can be maintained in a vacuum state. A mechanism (e.g., a processing gas supply part, a plasma generation part, or the like, all not shown) for performing desired processing on the substrate W is provided at the upper part of the processing chamber 10. An exhaust device 12 having a vacuum pump that can reduce a pressure in the processing chamber 10 to a vacuum level is connected to the bottom portion of the processing chamber 10. A transfer port 13 for loading and unloading the substrate W is formed at the sidewall of the processing chamber 10. The transfer port 13 is opened and closed by a gate valve 14. By opening the gate valve 14, the processing chamber 10 communicates with a vacuum transfer chamber (not shown) adjacent to the processing chamber 10, and the substrate W is loaded and unloaded by a transfer device (not shown) of the vacuum transfer chamber.

The substrate placing table 40 is provided in the processing chamber 10, and the upper surface of the substrate placing table 40 serves as a substrate placing surface on which the substrate W is placed. The substrate placing table 40 includes a main body 41 having a plate shape with a diameter slightly greater than that of the substrate W and made of a metal material, e.g., aluminum, and an electrostatic chuck 46 provided on the main body 41 to electrostatically attract the substrate W. The upper surface of the electrostatic chuck 46 serves as a substrate placing surface, and an electrode 46a is embedded inside a dielectric. When a DC voltage is applied from a DC power supply 48 to the electrode 46a, the substrate W placed on the substrate placing surface is attracted by the electrostatic force. The main body 41 is supported by a cylindrical support 47 extending downward from the center of the bottom surface. Further, the substrate placing table 40 is configured to be heated or cooled by a temperature control mechanism (not shown). Further, the substrate placing table 40 may be configured to be rotatable by a rotation mechanism (not shown).

The substrate processing apparatus 1 further includes an electrostatic capacitance detection part 49 that detects the electrostatic capacitance of the electrostatic chuck 46. The detected capacitance varies depending on the state of the electrostatic chuck 46 (for example, whether or not the substrate W is placed on the substrate placing surface, the thickness of the dielectric, the contamination of the substrate placing surface, or the like), the contact/non-contact state between the substrate W and a lift pin(s) 51 to be described later, the state of power application to the electrode 46a (whether or not the substrate W is electrostatically attracted), or the like. The electrostatic capacitance detection part 49 is provided at the DC power supply 48, for example. The electrostatic capacitance detection part 49 detects the electrostatic capacitance of the electrostatic chuck 46. The electrostatic chuck 46 shown in FIG. 1 has bipolar electrodes 46a, and the electrostatic capacitance detection part 49 detects the electrostatic capacitance between the bipolar electrodes 46a. Further, the electrostatic chuck 46 may have a monopolar electrode 46a. In this case, the electrostatic capacitance detection part 49 detects the electrostatic capacitance between the monopolar electrode 46a and the ground potential.

The substrate lifting mechanism 50 includes a plurality of lift pins 51 for raising and lowering the substrate W, a support plate 52 for supporting the lift pins 51, a lifting rod 53 for raising and lowering the support plate 52, a driving mechanism 54, and a bellows 57.

The plurality of lift pins 51 are inserted into holes 44 formed in the substrate placing table 40, and are configured to protrude from and retract below the substrate placing surface. The number and arrangement of the lift pins 51 are appropriately set according to the shape and size of the substrate W. Further, the material of the lift pins 51 may be a conductor such as Ti or an insulator (dielectric) such as Al₂O₃. The support plate 52 is provided below the substrate placing table 40, and is configured to be raised and lowered together with the lift pins 51 while supporting the plurality of lift pins 51. One end of the lifting rod 53 is fixed to the bottom surface of the support plate 52 and extends downward, thereby reaching the outside of the processing chamber 10 through an insertion hole 15 provided in the bottom wall of the processing chamber 10.

The driving mechanism 54 has a motor 55 and a ball screw mechanism 56. The motor 55 rotates a ball screw (not shown) of the ball screw mechanism 56, and moves a moving member 59 guided by a guide member (not shown) in the vertical direction. The lower end of the lifting rod 53 is attached to the moving member 59. By rotating the motor 55, the lifting rod 53 is raised and lowered via the ball screw mechanism 56 and the moving member 59 and, thus, the lift pins 51 are raised and lowered together with the support plate 52. The motor 55 may be a servo motor or a stepping motor.

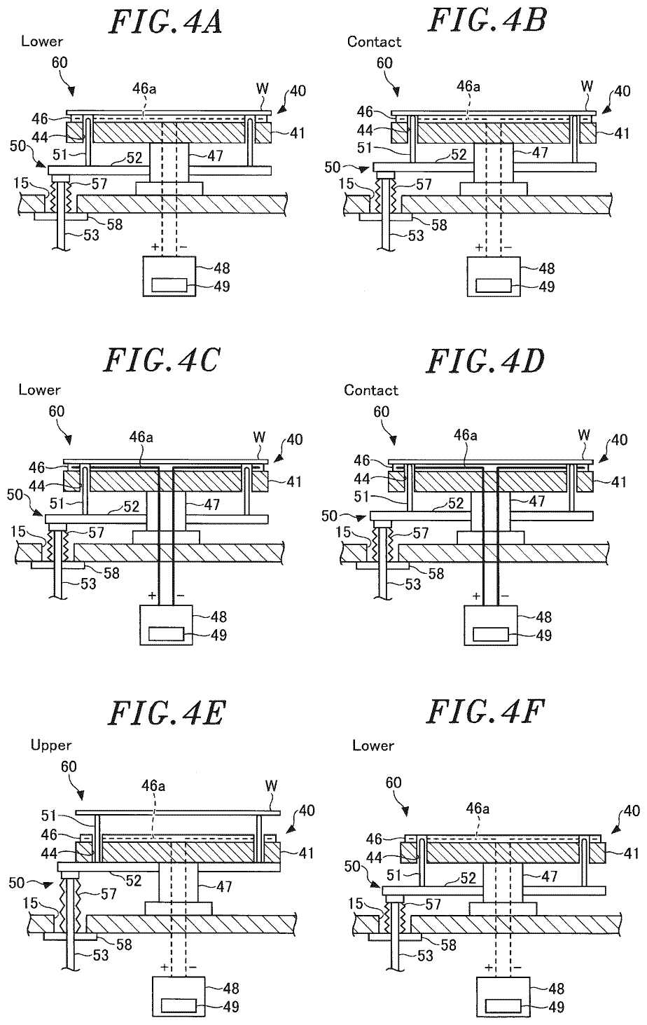

The tip ends of the lift pins 51 are moved between a lower end position (see FIGS. 4A, 4C, and 4F) that is lower than the substrate placing surface and recessed into the holes 44 of the substrate placing table 40, and an upper end position (see FIG. 4E) that is higher than the substrate placing surface of the substrate placing table 40. In addition, a contact position (see FIGS. 4B and 4D) exists between the lower end position and the upper end position. The contact position is the position where the tip ends of the lift pins 51 are brought into contact with the substrate W placed on the substrate placing surface of the substrate placing table 40. Further, the origin of the tip ends of the lift pins 51 is the lower end position, and the contact position is defined as a height position with respect to the lower end position which is the origin. The contact position can be adjusted by adjusting the lower end position that is the origin.

The portion corresponding to the through-hole 15 on the outer surface of the bottom wall of the processing chamber 10 is shielded by a shielding plate 58 having a hole into which the lift rod 53 is inserted, and the bellows 57 is provided around the lift rod 53 between the support plate 52 and the shielding plate 58. The bellows 57 shields the vacuum atmosphere in the processing chamber 10 from the atmospheric atmosphere outside the processing chamber 10.

The controller 70 controls individual components of the substrate processing apparatus 1, such as the DC power supply 48, the exhaust device 12, the driving mechanism 54, and the like. The controller 70 partially functions as a controller for the substrate placing mechanism 60. Further, the controller 70 receives the electrostatic capacitance detected by the electrostatic capacitance detection part 49 and determines the state of the substrate placing table 40.

### Operation of Substrate Processing Apparatus 1

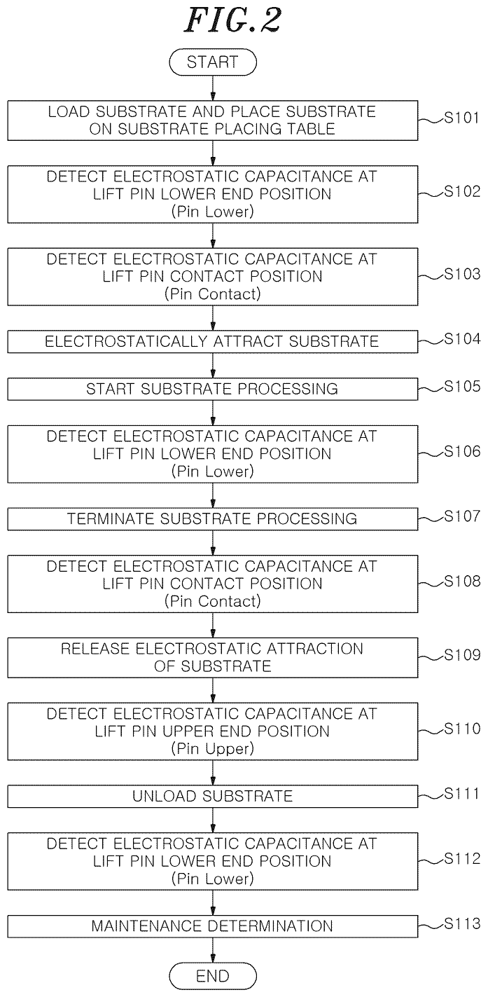

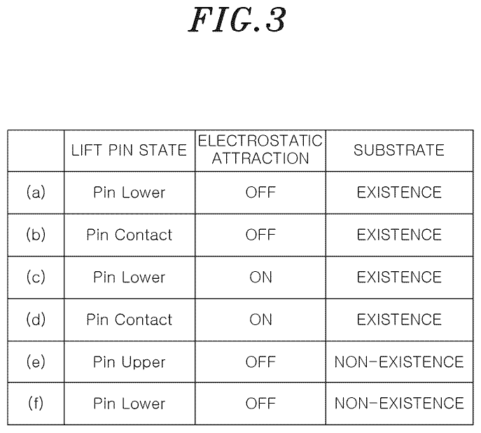

An example of the operation of the substrate processing apparatus 1 according to the present embodiment will be described with reference to FIGS. 2 to 4. FIG. 2 is an example of a flowchart showing the operation of the substrate processing apparatus 1 according to the present embodiment. FIG. 3 is an example of a diagram explaining respective states of capacitance measurement. FIGS. 4A to 4F are examples of partially enlarged cross-sectional views explaining the state of the substrate placing table 40 in the respective states of the electrostatic capacitance measurement.

In step S101, the substrate W is loaded into the processing chamber 10 and placed on the substrate placing table 40. The controller 70 opens the gate valve 14 and controls a transfer device (not shown) to place a pick (not shown) holding the substrate W on the substrate placing table 40. Next, the controller 70 controls the driving mechanism 54 (the motor 55) to raise the lift pins 51 to the upper end position. As a result, the substrate W supported by the pick of the transfer device is transferred to the lift pins 51. Next, the controller 70 controls the transfer device (not shown) to retract the pick from the loading/unloading port 13, and closes the gate valve 14. Next, the controller 70 controls the driving mechanism 54 (the motor 55) to lower the lift pins 51 to the lower end position (origin position). As a result, the substrate W supported by the lift pins 51 is placed on the substrate placing surface of the substrate placing table 40.

In step S102, the electrostatic capacitance is detected when the lift pins are positioned at the lower end position. The controller 70 controls the driving mechanism 54 (the motor 55) to lower the lift pins 51 to the lower end position (origin position) or to maintain the lower end position (origin position).

Label (a) in FIG. 3 shows the measurement state in step S102. FIG. 4A is an example of a partially enlarged cross-sectional view explaining the state of the substrate placing table 40 in step S102.

The substrate W is placed on the substrate placing surface of the substrate placing table 40 (substrate: existence). In addition, the tip ends of the lift pins 51 are located at the lower end position (lift pin state: Pin Lower) recessed into the holes 44 of the substrate placing table 40, which is lower than the substrate placing surface of the substrate placing table 40 on which the substrate W is placed. In other words, the backside of the substrate W and the tip ends of the lift pins 51 are not in contact with each other. Further, the DC power supply 48 is not applying a voltage to the electrode 46a (electrostatic attraction: off). The electrostatic capacitance detection part 49 measures the electrostatic capacitance of the electrostatic chuck 46.

In step S103, the electrostatic capacitance is detected when the lift pins are positioned at the contact position. The controller 70 controls the driving mechanism 54 (the motor 55) to raise the lift pins 51 to the contact position. Further, when the lift pins 51 are raised to the contact position, a certain gap may exist between the backside of the substrate W and the substrate placing surface of the electrostatic chuck 46.

Label (b) in FIG. 3 shows the measurement state in step S103. FIG. 4B is an example of a partially enlarged cross-sectional view illustrating the state of the substrate placing table 40 in step S103.

The substrate W is placed on the substrate placing surface of the substrate placing table 40 (substrate: existence). The tip ends of the lift pins 51 are located at a position (lift pin state: Pin Contact) where they are brought into contact with the substrate W placed on the substrate placing table 40. In other words, the backside of the substrate W and the tip ends of the lift pins 51 are in contact with each other. Further, the DC power supply 48 is not applying a voltage to the electrode 46a (electrostatic attraction: off). The electrostatic capacitance detection part 49 measures the electrostatic capacitance of the electrostatic chuck 46. After the measurement, the controller 70 controls the driving mechanism 54 (motor 55) to lower the lift pins 51 to the lower end position (origin position).

In step S104, the substrate W is electrostatically attracted. The controller 70 controls the DC power supply 48 to apply a voltage to the electrode 46a. As a result, the substrate W is electrostatically attracted to the electrostatic chuck 46.

In step S105, the substrate processing is started. For example, desired processing is performed on the surface of the substrate W by supplying a processing gas into the process chamber 10, producing plasma of the processing gas in the process chamber 10, releasing sputtered particles in the process chamber 10, or the like.

In step S106, the electrostatic capacitance is detected when the lift pins are positioned at the lower end position. The controller 70 controls the driving mechanism 54 (the motor 55) to lower the lift pins 51 to the lower end position (origin position) or to maintain the lower end position (origin position).

Label (c) in FIG. 3 shows the measurement state in step S106. FIG. 4C is an example of a partially enlarged cross-sectional view explaining the state of the substrate placing table 40 in step S106.

The substrate W is placed on the substrate placing surface of the substrate placing table 40 (substrate: existence). In addition, the tip ends of the lift pins 51 are located at the lower end position (lift pin state: Pin Lower) recessed into the holes 44 of the substrate placing table 40, which is lower than the substrate placing surface of the substrate placing table 40 on which the substrate W is placed. In other words, the backside of the substrate W and the tip ends of the lift pins 51 are not in contact with each other. Further, the DC power supply 48 is applying a voltage to the electrode 46a (electrostatic attraction: on). The electrostatic capacitance detector 49 measures the electrostatic capacitance of the electrostatic chuck 46.

In step S107, the substrate processing is terminated.

In step S108, the electrostatic capacitance is detected when the lift pins are positioned at the contact position. The controller 70 controls the driving mechanism 54 (the motor 55) to raise the lift pins 51 to the contact position. When the lift pins 51 are raised to the contact position, a certain gap may exist between the backside of the substrate W and the substrate placing surface of the electrostatic chuck 46. Further, the force in which the lift pins 51 are raised by the driving mechanism 54 (the motor 55) is greater than the force in which the electrostatic chuck 46 electrostatically attracts the substrate W, so that the substrate W is separated from the substrate placing surface of the electrostatic chuck 46 against the electrostatic attractive force.

Label (d) in FIG. 3 shows the measurement state in step S108. FIG. 4D is an example of a partially enlarged cross-sectional view illustrating the state of the substrate placing table 40 in step S108.

The substrate W is placed on the substrate placing surface of the substrate placing table 40 (substrate: existence). The tip ends of the lift pins 51 are located at a position (lift pin state: Pin Contact) where they are brought into contact with the substrate W placed on the substrate placing table 40. In other words, the backside of the substrate W and the tip ends of the lift pins 51 are in contact with each other. Further, the DC power supply 48 is applying a voltage to the electrode 46a (electrostatic attraction: on). The electrostatic capacitance detector 49 measures the electrostatic capacitance of the electrostatic chuck 46. After the measurement, the controller 70 controls the driving mechanism 54 (the motor 55) to lower the lift pins 51 to the lower end position (origin position).

In step S109, the electrostatic attraction of the substrate W is released. The controller 70 stops the application of voltage to the electrode 46a by the DC power supply 48. Accordingly, the electrostatic attraction of the substrate W by the electrostatic chuck 46 is released.

In step S110, the electrostatic capacitance is detected when the lift pins are positioned at the upper end position. The controller 70 controls the driving mechanism 54 (the motor 55) to raise the lift pins 51 to the upper end position. In this case, the substrate W placed on the substrate placing surface of the substrate placing table 40 is lifted by the lift pins 51.

Label (e) in FIG. 3 shows the measurement state in step S110. FIG. 4E is an example of a partially enlarged cross-sectional view explaining the state of the substrate placing table 40 in step S110.

The tip ends of the lift pins 51 are located at the upper end position (lift pin state: Pin Upper) that is higher than the substrate placing surface of the substrate placing table 40 on which the substrate W is placed. In other words, the backside of the substrate W and the tip ends of the lift pins 51 are in contact with each other. The substrate W is supported by the lift pins 51, and the substrate W is not placed on the substrate placing surface of the substrate placing table 40 (substrate: non-existence). The DC power supply 48 is not applying a voltage to the electrode 46a (electrostatic attraction: off). The electrostatic capacitance detection part 49 measures the electrostatic capacitance of the electrostatic chuck 46.

In step S111, the substrate W is unloaded from the processing chamber 10. The controller 70 opens the gate valve 14, and controls the transfer device (not shown) to locate a pick (not shown) to a position under the substrate W supported by the lift pins 51. Next, the controller 70 controls the driving mechanism 54 (the motor 55) to lower the lift pins 51 to the lower end position (origin position). As a result, the substrate W supported by the lift pins 51 is transferred to the pick of the transfer device. Next, the controller 70 controls the transfer device (not shown) to retract the pick holding the substrate W from the loading/unloading port 13, and closes the gate valve 14.

In step S112, the electrostatic capacitance is detected when the lift pins are positioned at the lower end position. The controller 70 controls the driving mechanism 54 (the motor 55) to lower the lift pins 51 to the lower end position (origin position) or to maintain the lower end position (origin position).

Label (f) in FIG. 3 shows the measurement state in step S112. FIG. 4F is an example of a partially enlarged cross-sectional view explaining the state of the substrate placing table 40 in step S112.

The substrate W is not placed on the substrate placing surface of the substrate placing table 40 (substrate: non-existence). The tip ends of the lift pins 51 are located at the lower end position (Lift pin state: Pin Lower) recessed into the holes 44 of the substrate placing table 40, which is lower than the substrate placing surface of the substrate placing table 40 on which the substrate W is placed. In other words, the backside of the substrate W and the tip ends of the lift pins 51 are not in contact with each other. The DC power supply 48 is not applying a voltage to the electrode 46a (electrostatic attraction: Off). The electrostatic capacitance detection part 49 measures the electrostatic capacitance of the electrostatic chuck 46.

In step S113, the controller 70 performs maintenance determination for the substrate placing table 40. Here, the state of the electrostatic chuck 46 of the substrate placing table 40 is determined based on the electrostatic capacitance detected in steps S102, S103, S106, S108, S110, and S112. Among the attraction parameters of the electrostatic chuck 46, the electrostatic capacitance is quantified, and the determination is made based on whether or not the quantified capacitance is within a predetermined range.

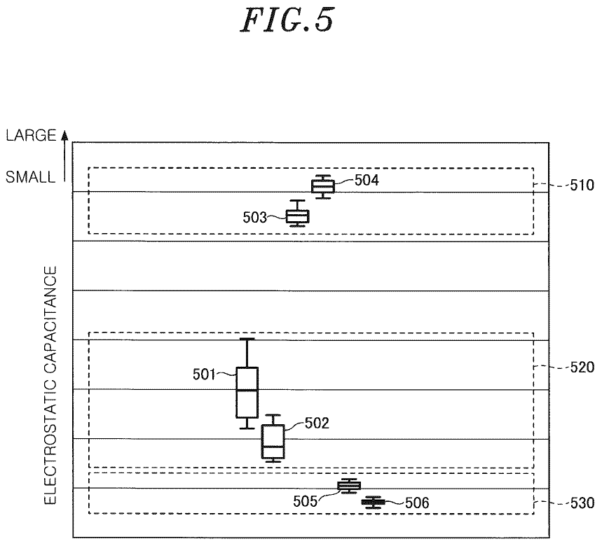

FIG. 5 is an example of an electrostatic capacitance graph. Here, the processes of steps S101 to S112 are repeated to perform substrate processing on a plurality of substrates W and measure the electrostatic capacitance. The vertical axis of the graph in FIG. 5 represents an electrostatic capacitance.

Reference numeral 501 is an example of a box-and-whisker plot of the electrostatic capacitance detected in step S102. Reference numeral 502 is an example of a box-and-whisker plot of the electrostatic capacitance detected in step S103. Reference numeral 503 is an example of a box and whisker plot of the electrostatic capacitance detected in step S106. Reference numeral 504 is an example of a box-and-whisker plot of the electrostatic capacitance detected in step S108. Reference numeral 505 is an example of a box-and-whisker plot of the electrostatic capacitance detected in step S110. Reference numeral 506 is an example of a box-and-whisker plot of the electrostatic capacitance detected in step S112.

A range 510 is an electrostatic capacitance range in which the electrostatic chuck 46 is determined to be normal when the substrate W is placed on the substrate placing surface of the substrate placing table 40 and electrostatically attracted thereto (S106), or when the substrate W is located near the substrate placing surface of the substrate placing table 40 and electrostatically attracted (S108).

A range 520 is an electrostatic capacitance range in which the electrostatic chuck 46 is determined to be normal when the substrate W is placed on the substrate placing surface of the substrate placing table 40 and is not electrostatically attracted (S102), or when the substrate W is located near the substrate placing surface of the substrate placing table 40 and is not electrostatically attracted (S103).

A range 530 is an electrostatic capacitance range in which the electrostatic chuck 46 is determined to be normal when the substrate W is sufficiently separated from the substrate placing surface of the substrate placing table 40 and is not electrostatically attracted (S110, S112).

The controller 70 determines that the substrate placing table 40 is normal when the electrostatic capacitances (501 to 506) detected in the respective steps are within the corresponding capacitance ranges (510 to 530). In other words, the controller 70 determines that the maintenance is not required.

On the other hand, when any of the electrostatic capacitances 501 to 506 is not within the corresponding capacitance range (510 to 530), it is determined that the maintenance of the substrate placing table 40 is required.

When the electrostatic capacitances measured in steps S102 and S103 are within the range 520, it can be determined that the substrate W is normally placed on the substrate placing surface. When the electrostatic capacitances are not within the range 520, it can be determined that the substrate W is abnormally placed on the substrate placing surface.

When the amount of change (difference) between the electrostatic capacitances measured in steps S103 and S102 is greater than or equal to a predetermined threshold, it can be determined that the tip ends of the lift pins 51 are in contact with the substrate W. On the other hand, if the amount of change (difference) is less than the predetermined threshold, it can be determined that the tip ends of the lift pins 51 are not in contact with the substrate W.

When the amount of change (difference) between the electrostatic capacitance measured in step S108 and the electrostatic capacitance measured in step S106 is greater than or equal to the predetermined threshold, it can be determined that the tip ends of the lift pins 51 are in contact with the substrate W. On the other hand, when the amount of change (difference) is less than the predetermined threshold, it can be determined that the tip ends of the lift pins 51 are not in contact with the substrate W.

When the amount of change (difference) between the electrostatic capacitance measured in step S110 and the electrostatic capacitance measured in step S112 is greater than or equal to the predetermined threshold, it can be determined that the tip ends of the lift pins 51 are in contact with the substrate W. On the other hand, when the amount of change (difference) is less than the predetermined threshold, it can be determined that the tip ends of the lift pins 51 are not in contact with the substrate W.

When the electrostatic capacitances measured in steps S106 and S108 are within the range 510, it can be determined that the substrate W is normally electrostatically attracted. When they are not within the range 510, it can be determined that the substrate W is abnormally electrostatically attracted.

When the electrostatic capacitances measured in steps S110 and S112 are within the range 530, it can be determined that the substrate W is normally separated from the substrate placing table. When they are not within the range 530, it can be determined that the substrate W is abnormally separated from the substrate placing table.

For example, when the attractive force of the electrostatic chuck 46 decreases due to the deterioration of the substrate placing table 40 over time, the electrostatic capacitances indicated by the reference numerals 503 and 504 decrease. When the electrostatic capacitances indicated by the reference numerals 503 and 504 becomes lower than the range 510, it is determined that the maintenance of the substrate placing table 40 is required.

When the amount of change (difference) between the electrostatic capacitance before the electrostatic attraction (S102 and S103 in FIG. 2; see reference numbers 501 and 502 in FIG. 5) and the electrostatic capacitance after the electrostatic attraction (S106 and S108 in FIG. 2; see reference numbers 503 and 504 in FIG. 5) is greater than or equal to the predetermined threshold, it is determined that the maintenance is not required. On the other hand, when the amount of change (difference) is less than the predetermined threshold, it is determined that the maintenance is required.

Further, the controller 70 may determine that the substrate W is normally attracted when the amount of change (difference) is greater than or equal to the predetermined threshold, and may determine that the substrate W is abnormally attracted when the amount of change (difference) is less than the predetermined threshold.

When the amount of change (difference) between the electrostatic capacitance in the electrostatically attracted state (S106 and S108 in FIG. 2; see reference numbers 503 and 504 in FIG. 5) and the electrostatic capacitance in the state after the electrostatic attraction is released (S110 and S112 in FIG. 2; see reference numbers 505 and 506 in FIG. 5) is greater than or equal to the predetermined threshold, it is determined that the maintenance is not required. On the other hand, when the amount of change (difference) is less than the predetermined threshold, it is determined that the maintenance is required.

Further, the controller 70 may determine that the attraction of the substrate W is normally released when the amount of change (difference) is greater than or equal to the predetermined threshold, and may determine that the attraction of the substrate W is abnormally released when the amount of change (difference) is less than the predetermined threshold.

When the amount of change (difference) between the electrostatic capacitance in a state where no substrate W is placed on the substrate placing surface (S110 and S112 in FIG. 2; see reference numbers 505 and 506 in FIG. 5) and the electrostatic capacitance in a state where the substrate W is placed on the substrate placing surface (S102 and S103 in FIG. 2; see reference numbers 501 and 502 in FIG. 5) is greater than or equal to the predetermined threshold, it is determined that the maintenance is not required. On the other hand, when the amount of change (difference) is less than the predetermined threshold, it is determined that the maintenance is required.

The electrostatic capacitance measured for each substrate W is stored as data (see, e.g., the box-and-whisker plots indicated by reference numbers 501 to 506) in the memory of the controller 70. Whether or not the maintenance is required may be determined based on the change in the stored data.

Conventionally, as a maintenance method for the substrate placing table 40, there is known a maintenance method in which the substrate placing table 40 is replaced at a predetermined maintenance interval unless there is an initial defect, breakage, contamination, or other sudden malfunction. In this maintenance method, the substrate placing table 40 is replaced even if it is within a normal performance range.

On the other hand, in the substrate processing apparatus 1, the controller 70 determines whether or not the maintenance of the substrate placing table 40 is required based on the detected capacitance. Accordingly, whether or not the maintenance is required is determined depending on the deterioration of the substrate placing table 40 over time. Therefore, if the substrate placing table 40 is within the normal performance range, the substrate placing table 40 can be used continuously, and the predetermined maintenance interval can be extended. In other words, the downtime of the substrate processing apparatus 1 is reduced, and the operating rate of the substrate processing apparatus 1 is improved.

While the substrate processing apparatus 1 has been described, the present disclosure is not limited to the above-described embodiments, and various changes and improvements can be made without departing from the scope of the appended claims and the gist thereof.

1. A substrate processing apparatus comprising:
a substrate placing table having an electrostatic chuck configured to electrostatically attract a substrate by applying a voltage to an electrode of the electrostatic chuck;
a lift pin configured to protrude from and retract below a substrate placing surface of the substrate placing table;
a driving mechanism configured to raise and lower the lift pin;
an electrostatic capacitance detection part configured to detect an electrostatic capacitance of the electrostatic chuck; and
a controller configured to determine a state of the electrostatic chuck based on the electrostatic capacitance detected by the electrostatic capacitance detection part.

2. The substrate processing apparatus of claim 1, wherein the controller determines an attraction state of the substrate placed on the substrate placing surface, based on an electrostatic capacitance before a voltage is applied to the electrode of the electrostatic chuck and an electrostatic capacitance after a voltage is applied to the electrode of the electrostatic chuck.

3. The substrate processing apparatus of claim 2, wherein the controller determines the attraction state of the substrate placed on the substrate placing surface, based on an amount of change between the electrostatic capacitance before the voltage is applied to the electrode of the electrostatic chuck and the electrostatic capacitance after the voltage is applied to the electrode of the electrostatic chuck.

4. The substrate processing apparatus of claim 1, wherein the controller determines the state of the electrostatic chuck based on whether the detected electrostatic capacitance is within a predetermined range.

5. A method for determining a state of a substrate processing apparatus,
wherein the substrate processing apparatus includes:
a substrate placing table having an electrostatic chuck configured to electrostatically attract a substrate by applying a voltage to an electrode of the electrostatic chuck;
a lift pin configured to protrude from and retract below a substrate placing surface of the substrate placing table;
a driving mechanism configured to raise and lower the lift pin; and
an electrostatic capacitance detection part configured to detect an electrostatic capacitance of the electrostatic chuck,
the method comprising:
determining a state of the electrostatic chuck based on the electrostatic capacitance detected by the electrostatic capacitance detection part.
